(19) United States
(12) Patent Application Publication
(10) Pub. No.: US 2024/0162036 A1
(43) Pub. Date: May 16, 2024

(54) SELECTIVE DEPOSITION OF MATERIAL COMPRISING SILICON AND NITROGEN

(71) Applicant: ASM IP Holding B.V., Almere (NL)

(72) Inventors: Viraj Madhiwala, Heverlee (BE); Eva Elisabeth Tois, Espoo (FI); Daniele Chiappe, Freiburg (DE); Marko Tuominen, Helsinki (FI)

(21) Appl. No.: 18/388,548

(22) Filed: Nov. 10, 2023

Related U.S. Application Data
(60) Provisional application No. 63/425,325, filed on Nov. 15, 2022.

(51) Int. Cl. H01L 21/02; C23C 16/30; C23C 16/34; C23C 16/36; C23C 16/455; C23C 16/56

(52) U.S. Cl. CPC H01L 21/0217; C23C 16/308; C23C 16/345; C23C 16/36; C23C 16/45527; C23C 16/56; H01L 21/0214; H01L 21/02167; H01L 21/02211; H01L 21/0228; H01L 21/02312

(57) ABSTRACT

The disclosure relates to methods and deposition assemblies for selectively depositing material including silicon and nitrogen on a first surface of a substrate relative to the second surface of the same substrate. In the disclosure, material including silicon and nitrogen is selectively deposited on a first surface of a substrate relative to a second surface of the same substrate by a cyclic deposition process by providing a substrate in a reaction chamber, providing a silicon precursor comprising silicon and halogen into the reaction chamber in a vapor phase and providing a nitrogen precursor into the reaction chamber in a vapor phase to form the material including silicon and nitrogen on the first surface.

### CROSS-REFERENCE TO RELATED APPLICATIONS

This application claims priority to and the benefit of U.S. Provisional Application No. 63/425,325, filed Nov. 15, 2022, the entirety of which is incorporated by reference herein.

### FIELD OF INVENTION

The present disclosure relates to methods and apparatuses for the manufacture of semiconductor devices. More particularly, the disclosure relates to methods and apparatuses for selectively depositing material comprising silicon and nitrogen on a substrate, and layers comprising material comprising silicon and nitrogen.

### BACKGROUND OF THE DISCLOSURE

Semiconductor device fabrication processes generally use advanced deposition methods. Patterning is conventionally used in depositing different materials on semiconductor substrates. Selective deposition, which is receiving increasing interest among semiconductor manufacturers, could enable a decrease in steps needed for conventional patterning, reducing the cost of processing. Selective deposition could also allow enhanced scaling in narrow structures. Various alternatives for bringing about selective deposition have been proposed, and additional improvements are needed to expand the use of selective deposition in industrial-scale device manufacturing.

Particularly, material comprising silicon and nitrogen, such as silicon nitride, silicon oxynitride and silicon carbonitride may be used in many applications in semiconductor industry. For example material comprising silicon and nitrogen may be used as an etch-stop layer in forming various semiconductor structures, as a channel material in a gate stack, and in novel memory applications. Such material comprising silicon and nitrogen is difficult to deposit without using plasma and to achieve desired material properties, such as etch resistance. Thus, there is need in the art for new selective thermal deposition processes of material comprising silicon and nitrogen.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of selectively depositing material comprising silicon and nitrogen on a substrate, to a material layer comprising silicon and nitrogen, to a semiconductor structure and a device, and to deposition assemblies for selectively depositing material comprising silicon and nitrogen on a substrate.

In an aspect, a method of selectively depositing material comprising silicon and nitrogen on a first surface of a substrate relative to a second surface of the same substrate by a cyclic deposition process is disclosed. The method comprises providing a substrate in a reaction chamber, providing a silicon precursor comprising silicon and halogen into the reaction chamber in a vapor phase; and providing a nitrogen precursor into the reaction chamber in a vapor phase to form material comprising silicon and nitrogen on the first surface.

In some embodiments, the silicon precursor comprises a halosilane. In some embodiments, the halosilane is fully halogenated. In some embodiments, the halogen in the halosilane is selected from iodine and chlorine. In some embodiments, the halosilane is a fully halogenated chlorosilane. In some embodiments, the halosilane is selected from a group consisting of monosilanes, disilanes and trisilanes.

In some embodiments, the nitrogen precursor consists of nitrogen and hydrogen. In some embodiments, the nitrogen precursor is selected from a group consisting, ammonia, hydrazine and tert-butylhydrazine.

In some embodiments, the second surface is passivated. In some embodiments, the passivation comprises an organic polymer, a self-assembled monolayer (SAM) or a small-molecular inhibitor.

In some embodiments, the first surface is a conductive surface. In some embodiments, the first surface comprises a metal. In some embodiments, the first surface comprises elemental metal. In some embodiments, the metal is selected from a group consisting of Cu, Co, Ru, W, Ti, Al, Ta and Mo.

In some embodiments, the second surface comprises silicon-based dielectric material. In some embodiments, the second surface comprises a low k material. In some embodiments, the second surface comprises passivation. In some embodiments, the passivation agent is selected from a group consisting of silylating agents and a materials comprising polyimide.

In some embodiments, the first surface is a dielectric surface. In some embodiments, the dielectric surface comprises silicon. In some embodiments, the dielectric surface comprises material selected from a group comprising SiO2, SiN, SiOC, SiON, SiOCN and combinations thereof. In some embodiments, the dielectric surface comprises a metal oxide. In some embodiments, the metal oxide is selected from aluminum oxide, hafnium oxide and zirconium oxide.

In some embodiments, the method comprises, before providing the silicon precursor into the reaction chamber, treating the first surface with a silylation agent and thereafter depositing an organic polymer on the second surface.

In some embodiments, the deposited material comprising silicon and nitrogen consists essentially of, or consists of, silicon, nitrogen and hydrogen. In some embodiments, the deposited material comprising silicon and nitrogen consists essentially of, or consists of silicon, nitrogen, hydrogen and a fourth element. In some embodiments, the fourth element is selected from a group consisting of oxygen and carbon. In some embodiments, the deposited material comprising silicon and nitrogen consists essentially or consists of silicon, nitrogen, hydrogen, carbon and oxygen. In some embodiments, the deposited material comprising silicon and nitrogen comprises less than about 4 at-%, or less than about 2 at-% halogen.

In some embodiments, the method does not comprise providing a metal-containing reactant into the reaction chamber. In some embodiments, the method comprises at least one etch-back step. In some embodiments, the selectivity of deposition of the material comprising silicon and nitrogen on the first surface relative to the second surface is greater than about 50%.

In some embodiments, the method is performed at a temperature between about 200° C. and about 450° C. In some embodiments, the method is performed at a pressure of below about 10 Torr.

In another aspect, a method of selectively depositing an etch stop layer by depositing etch stop material comprising silicon and nitrogen on a first surface of a substrate relative to a second surface of the same substrate by a cyclic deposition process is disclosed. The method comprising providing a substrate in a reaction chamber, providing a silicon precursor comprising silicon and halogen into the reaction chamber in a vapor phase and providing a nitrogen precursor into the reaction chamber in a vapor phase to form etch stop material comprising silicon and nitrogen on the first surface. In some embodiments, the WERR of the etch stop material is at least about XXX.

In yet another aspect, a deposition assembly for selectively depositing material comprising silicon and nitrogen on a first surface of a substrate relative to the second surface of the same substrate is disclosed. The deposition assembly comprises one or more reaction chambers constructed and arranged to hold the substrate and a precursor injector system constructed and arranged to provide a silicon precursor and a nitrogen precursor into the reaction chamber in a vapor phase. The deposition assembly comprises a first reactant vessel constructed and arranged to contain the silicon precursor; and a second reactant vessel constructed and arranged to contain the nitrogen precursor; and the assembly is constructed and arranged to provide the silicon precursor and the nitrogen precursor via the precursor injector system to the reaction chamber to deposit material comprising silicon and nitrogen on the first surface.

In some embodiments, the deposition assembly further comprises a passivation system constructed and arranged to provide a passivation agent into a reaction chamber of the deposition assembly.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings

FIG. 1 is a schematic presentation of selective deposition according to the current disclosure.

FIG. 2 is a block diagram of exemplary embodiments of a method according to the current disclosure.

FIG. 3 is a block diagram of exemplary embodiments of a method according to the current disclosure.

FIG. 4 is a block diagram of exemplary embodiments of a method according to the current disclosure.

FIG. 5 is a schematic presentation of a deposition assembly according to the current disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and deposition assemblies provided below is merely exemplary and is intended for purposes of illustration only. Although certain embodiments and examples are disclosed below, it will be understood by those in the art that the invention extends beyond the specifically disclosed embodiments and/or uses of the invention and obvious modifications and equivalents thereof. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other. The headings provided herein, if any, are for convenience only and do not necessarily affect the scope or meaning of the claimed invention.

### Substrate

In an aspect, a method of selectively depositing material comprising silicon and nitrogen on a first surface of a substrate relative to a second surface of the same substrate by a cyclic deposition process is disclosed.

As used herein, the term “substrate” may refer to any underlying material or materials that may be modified, or upon which, a device, a circuit, material or a material layer may be formed. A substrate can include a bulk material, such as silicon (such as single-crystal silicon), other Group IV materials, such as germanium, or other semiconductor materials, such as a Group II-VI or Group III-V semiconductor materials. A substrate can include one or more layers overlying the bulk material. The substrate can include various topologies, such as gaps, including recesses, lines, trenches or spaces between elevated portions, such as fins, and the like formed within or on at least a portion of a layer of the substrate. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. A substate according to the current disclosure comprises two surfaces having different material properties.

The substrate may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

### First Surface and Second Surface

According to some aspects of the present disclosure, selective deposition can be used to deposit a material comprising silicon and nitrogen, such as a layer comprising silicon and nitrogen, on a first surface relative to a second surface of the substrate. The first surface and the second surface have different material properties. In some embodiments, the material comprising silicon and nitrogen is deposited on a first surface comprising a metal or metallic material relative to a second surface comprising a dielectric material. However, in some embodiments, the material comprising silicon and nitrogen is deposited on a first surface comprising a dielectric material relative to a second surface comprising a metal or metallic material.

The term dielectric is used in the description herein for the sake of simplicity in distinguishing from the other surface, namely the metal or metallic surface. It will be understood by those skilled in the art that not all non-conducting surfaces are dielectric surfaces. For example, the metal or metallic surface may comprise an oxidized metal surface that is electrically non-conducting or has a very high resistivity. Selective deposition processes taught herein can deposit on dielectric surfaces with minimal deposition on such adjacent non-conductive metal or metallic surfaces.

### Deposition on Metal Surface

In some embodiments, the first surface is a conductive surface. In some embodiments, the first surface comprises a metal. In some embodiments, the metal is selected from a group consisting of copper (Cu), cobalt (Co), ruthenium (Ru), tungsten (W), titanium (Ti), aluminum (Al), tantalum (Ta) and molybdenum (Mo). In some embodiments, the first surface comprises elemental metal. In some embodiments, the first surface consists essentially of, or consists of, elemental metal.

For embodiments in which one surface of the substrate comprises a metal, the surface is referred to as a metal surface. In some embodiments, a metal surface consists essentially of, or consists of one or more metals. A metal surface may be a metal surface or a metallic surface. In some embodiments the metal or metallic surface may comprise metal, metal oxides, and/or mixtures thereof. In some embodiments the metal or metallic surface may comprise surface oxidation. In some embodiments, the method according to the current disclosure comprises removing surface oxidation. Various reducing procedures may be used for the removal of the surface oxidation. In some embodiments the metal or metallic material of the metal or metallic surface is electrically conductive with or without surface oxidation. In some embodiments, metal or a metallic surface comprises one or more transition metals. In some embodiments, the metal or metallic surface comprises one or more transition metals from row 4 of the periodic table of elements. In some embodiments, the metal or metallic surface comprises one or more transition metals from groups 4 to 11 of the periodic table of elements. In some embodiments, a metal or metallic surface comprises aluminum Al. In some embodiments, a metal or metallic surface comprises Cu. In some embodiments, a metal or metallic surface comprises W. In some embodiments, a metal or metallic surface comprises Co. In some embodiments, a metal or metallic surface comprises nickel (Ni). In some embodiments, a metal or metallic surface comprises niobium (Nb). In some embodiments, the metal or metallic surface comprises iron (Fe). In some embodiments, the metal or metallic surface comprises Mo. In some embodiments, a metal or metallic surface comprises Ta. In some embodiments, a metal or metallic surface comprises Ti. In some embodiments, a metal or metallic surface comprises a metal selected from a group consisting of Ti, Al, manganese (Mn), Fe, Co, Ni, Cu, zinc (Zn), Nb, Mo, Ru and W. In some embodiments, the metal or metallic surface comprises one or more noble metals, such as Ru. In some embodiments, the metal or metallic surface comprises a conductive metal oxide. In some embodiments, the metal or metallic surface comprises a combination conductive materials.

In embodiments, in which the first surface is a metal or metallic surface, the second surface is a dielectric surface. In some embodiments, the second surface comprises silicon-based dielectric material. In some embodiments, the second surface comprises a low k material. A low k material according to the current disclosure is to be understood as a material such as SiO₂ or SiOC. Low k material may be defined as a material having a similar or lower k value as SiO₂. In some embodiments, a low k material has a lower k value than SiO₂. In some embodiments, the second surface comprises silicon. For example, the first surface may be a Ru surface, and the second surface may be a silicon oxide surface. In another example, the first surface may be a W surface, and the second surface may be a silicon oxide surface. The W surface may comprise tungsten oxide. The silicon oxide surface may be a native oxide surface. In some embodiments, the first surface may be a metal surface, such as, Mo, Cu, Co, W or Ru surface, and the second surface may be a SiC surface, or a SiOC surface, or a SiN surface or a SiGe surface or a SiON surface or a SiCN surface.

In some embodiments, the first surface is a dielectric surface and the second surface is a metal surface, and the passivation agent comprise a silylating agent, such as N-(trimethylsilyl) dimethylamine. In some embodiments, the first surface is a dielectric surface and the second surface is a metal surface, and the passivation comprise a polyimide layer. For example, polyimide passivation may be used in cases in which the first surface comprises Cu and/or Co.

### Deposition on Dielectric Surface

In some embodiments, the first surface is a dielectric surface. In some embodiments, the first surface is a low-k surface. In some embodiments, the first surface comprises silicon. In some embodiments, the first surface comprises an oxide. In some embodiments, the first surface comprises a nitride. Examples of silicon-comprising dielectric materials include silicon oxide-based materials, including grown or deposited silicon dioxide, doped and/or porous oxides and native oxide on silicon. In some embodiments, the first surface comprises silicon oxide. In some embodiments, the first surface is a silicon oxide surface, such as a native oxide surface, a thermal oxide surface or a chemical oxide surface. In some embodiments, the first surface comprises carbon. In some embodiments, the first surface comprises SiN. In some embodiments, the first surface comprises SiOC. In some embodiments, the first surface is an etch-stop layer. An etch-stop layer may comprise, for example a nitride. In some embodiments, the dielectric surface comprises material selected from a group comprising SiO₂, SiN, SiOC, SiON, SiOCN, SiGe and combinations thereof.

In some embodiments, the dielectric surface comprises a metal oxide. Thus, in some embodiments, a material comprising silicon and nitrogen is selectively deposited on a first metal oxide surface relative to a second surface. In some embodiments, the first surface comprises aluminum oxide. In some embodiments, the first surface is a high-k surface, such as hafnium oxide-comprising surface or a lanthanum oxide -comprising surface. In some embodiments, the metal oxide is selected from aluminum oxide, hafnium oxide and zirconium oxide.

In some embodiments, a material comprising silicon and nitrogen is selectively deposited on a first surface comprising a metal oxide relative to a second surface. A metal oxide surface may be, for example a tungsten oxide (WOx) surface, hafnium oxide (HfOx) surface, titanium oxide (TiOx) surface, aluminum oxide (AlOx) surface or zirconium oxide (ZrOx) surface. In some embodiments, a metal oxide surface is an oxidized surface of a metallic material. In some embodiments, a metal oxide surface is created by oxidizing at least the surface of a metallic material using oxygen compound, such as compounds comprising O₃, H₂O, H₂O₂, O₂, oxygen atoms, plasma or radicals or mixtures thereof. In some embodiments, a metal oxide surface is a native oxide formed on a metallic material. In some embodiments, the second surface comprises a material selected from a group consisting of a metal, amorphous carbon, metal oxide and metal nitride.

In some embodiments, a material comprising silicon and nitrogen, such as silicon nitride, silicon oxynitride or silicon carbonitride or a combination thereof, is selectively deposited on a first dielectric surface of a substrate relative to a second conductive (e.g., metal or metallic) surface of the substrate. In some embodiments, the first surface comprises hydroxyl (—OH) groups. In some embodiments, the first surface may additionally comprise hydrogen (—H) terminations, such as an HF dipped Si. In such embodiments, the surface of interest will be considered to comprise both the —H terminations and the material beneath the —H terminations. In some embodiments the dielectric surface and metal or metallic surface are adjacent to each other.

In some embodiments, a material comprising silicon and nitrogen such as silicon nitride, silicon oxynitride or silicon carbonitride or a combination thereof, is selectively deposited on a first dielectric surface of a substrate relative to a second, different dielectric surface. In some such embodiments, the dielectrics have different compositions (e.g. one of the surfaces comprises silicon, whereas the other does not comprise silicon).

In some embodiments, the second surface may comprise a passivated metal surface, for example a passivated Cu surface. That is, in some embodiments, the second surface may comprise a metal surface comprising a passivation agent, for example an organic passivation layer such as a polyimide passivation layer or a self-assembled monolayer. In some embodiments, the passivation layer remains on the second surface over at least two, such as at least about 10, about 20, about 50, about 100 or about 150 deposition cycles of the material comprising silicon and nitrogen. In other words, a passivation layer, such as polyimide-comprising layer, is used that is able to withstand the deposition conditions over an extended period of time.

### Surface Passivation

In some embodiments, the second surface comprises passivation. In some embodiments, the passivation is selected from a group consisting of silylating agents and a materials comprising polyimide. In some embodiments, the passivation comprises an organic polymer, a self-assembled monolayer (SAM) or a small-molecular inhibitor (SMI). Particularly, in embodiments in which the first surface is a metal or metallic surface, and the second surface is a dielectric surface comprising silicon, the second surface may comprise an organic polymer or an SMI. An SMI may be a silanol or a silicon-containing alkylamine. An organic polymer may be deposited through molecular layer deposition (MLD), and the organic polymer may comprise polyamic acid and/or polyimine. Further, in embodiments, in which the first surface is a dielectric surface comprising silicon, and the second surface is a metal or a metallic surface, the second surface may comprise an organic polymer. In such embodiments, the method may further comprise a pre-treatment using, for example, an SMI, to block the first surface from passivation, and to direct the organic polymer passivation on the second surface. Thus, the method according to the current disclosure may comprise a passivation treatment. The passivation treatment may be performed before the deposition and the passivation may be sustained throughout the deposition process. In some embodiments, the passivation treatment is performed intermittently with the deposition. In other words, the passivation may be renewed during the deposition process. In some embodiments, the method comprises proving a passivation agent, a silicon precursor and a nitrogen precursor alternately and sequentially into the reaction chamber.

For example, passivation may be performed after a predetermined number of deposition cycles. Such embodiments may be described as n[A+m(B+C)], wherein n denotes the number of deposition cycles in the process, A denotes performing passivation, m the number of deposition subcycles, wherein each subcycle comprises providing a silicon precursor (B) and providing a nitrogen precursor (C) into the reaction chamber.

In some embodiments, the method comprises, before providing the silicon precursor into the reaction chamber, treating the first surface with a silylation agent and thereafter depositing an organic polymer on the second surface. In some embodiments, the first surface is treated with a silylation agent directly before providing a silicon precursor into the reaction chamber. In some embodiments, the first surface is treated with a silylation agent directly before providing the substrate in the reaction chamber. By directly before is herein meant that the silylation agent treatment is performed in the same reaction chamber in which the deposition process is performed, in the same processing assembly in which the deposition process is performed or without an air- break between the silylation and the selective deposition process.

Thus, in some embodiments, a dielectric first surface is selectively blocked from passivation relative to the second surface, for example by selectively silylating the dielectric surface. In some embodiments, the dielectric surface is blocked by exposure to a silylation agent, such as allyltrimethylsilane (TMS-A), chlorotrimethylsilane (TMS-Cl), N-(trimenthylsilyl)imidazole (TMS-Im), octadecyltrichlorosilane (ODTCS), hexamethyldisilazane (HMDS), or N-(trimethylsilyl)dimethylamine (TMSDMA). In some embodiments, the blocking agent is a silanol, such as bis(tert-pentoxy)methylsilanol. In some embodiments, the blocking may aid in subsequent selective passivation of a metal surface. Thus, blocking a dielectric surface may, in some embodiments, allow the selective passivation of another surface, such as a metal surface or a dielectric surface of different composition. In some embodiments, the blocked dielectric surface may be treated, such as with a plasma. A second surface, such as a metal surface, is passivated, for example by selectively forming an organic polymer layer on the second surface. In some embodiments, blocking of the dielectric surface through, for example, silylation aids in the selectivity of the formation of the polymer passivation layer on a second surface. In some embodiments, blocking, such as silylation, does not require a specific removal step before depositing material comprising silicon and nitrogen on the first surface.

In some embodiments, particularly in embodiments, in which the first surface comprises a metal or a metallic material, blocking of the dielectric surface may be omitted.

Material comprising silicon and nitrogen is then selectively deposited on the first surface relative to the passivated second surface by providing a silicon precursor into the reaction chamber. The material comprising silicon and nitrogen may be deposited by a cyclical vapor deposition process in which the substrate is alternately contacted with the silicon precursor and the nitrogen precursor until a material comprising silicon and nitrogen of a desired thickness has been selectively deposited. Following the deposition of material comprising silicon and nitrogen, the passivation layer on the second surface may be removed, such as by etching. Etching may be performed, for example, by a plasma or a chemical treatment.

In some embodiments, a second dielectric surface, such as a silicon oxide surface, on a substrate is passivated by silylation with a silylating agent such as alyltrimethylsilane (TMS-A), chlorotrimethylsilane (TMS-Cl), N-(trimenthylsilyl)imidazole (TMS-Im), octadecyltrichlorosilane (ODTCS), hexamethyldisilazane (HMDS), or N-(trimethylsilyl)dimethylamine (TMSDMA). In such embodiments, a further passivation by an organic polymer may be omitted to selectively deposit a material comprising silicon and nitrogen on the metal or metallic first surface. In some embodiments, the second surface is not passivated with a self-assembled monolayer (SAM).

In some embodiments, the process according to the current disclosure comprises providing a passivation agent into the reaction chamber in a vapor phase to selectively passivate the second surface before depositing the material comprising silicon and nitrogen on the first surface. An organic polymer passivation may be selectively formed on the second surface relative to the first surface by providing a passivation agent into the reaction chamber. A passivation agent may be provided by a cyclic deposition process, such as MLD. For example, polyimide-comprising passivation layer may be deposited by providing a dianhydride and a diamine alternately and sequentially into a reaction chamber to form a passivation layer. The dianhydride may be pyromellitic dianhydride, and the diamine may be a 1,6-diaminohexane. In some embodiments, the passivating layer on the second surface inhibits, prevents or reduces the formation of the material comprising silicon and nitrogen on the second surface. In embodiments, in which the passivation is provided without a preceding blocking treatment, the second surface maybe a dielectric surface, and the first surface may be a metal or a metallic surface.

### Material Comprising Silicon and Nitrogen

Material comprising silicon and nitrogen according to the current disclosure may comprise, consist essentially of, or consist of silicon nitride, silicon oxynitride or silicon carbonitride. However, in some embodiments, the material comprising silicon and nitrogen comprises additional elements. In some embodiments, the material comprising silicon and nitrogen comprises hydrogen. In some embodiments, the deposited material comprising silicon and nitrogen consists essentially of, or consists of, silicon, nitrogen and hydrogen. In some embodiments, the deposited material comprising silicon and nitrogen consists essentially of, or consists of silicon, nitrogen, hydrogen and a fourth element. In some embodiments, the fourth element is selected from a group consisting of oxygen and carbon. In some embodiments, the deposited material comprising silicon and nitrogen consists essentially or consists of silicon, nitrogen, hydrogen, carbon and oxygen. In some embodiments, the deposited material comprising silicon and nitrogen comprises less than about 4 at-%, or less than about 2 at-% halogen. In some embodiments, the deposited material comprising silicon and nitrogen comprises less than about 1 at-% halogen, such as about 0.5 at-% or less halogen.

In some embodiments, a layer comprising material comprising silicon and nitrogen is deposited. As used herein, the term “layer” and/or “film” can refer to any continuous or non-continuous structure and material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. A seed layer may be a non-continuous layer serving to increase the rate of nucleation of another material. However, the seed layer may also be substantially or completely continuous.

A layer comprising silicon and nitrogen of desired thickness may be deposited by a cyclic deposition process according to the current disclosure. In some embodiments, the silicon and nitrogen-comprising layer is substantially continuous. In some embodiments, the silicon and nitrogen-comprising layer is continuous. In some embodiments, the silicon and nitrogen-comprising layer has an approximate thickness of at least about 0.5 nm. In some embodiments, the silicon and nitrogen-comprising layer has an approximate thickness of at least about 1 nm. In some embodiments, the silicon and nitrogen-comprising layer has an approximate thickness of at least about 5 nm. In some embodiments, the silicon and nitrogen-comprising layer has an approximate thickness of at least about 10 nm. In some embodiments, the silicon and nitrogen-comprising layer has an approximate thickness of about 1 nm to about 50 nm. In some embodiments, substantially or completely continuous silicon and nitrogen-comprising layers having a thickness of less than 10 nm, such as from about 4 nm to about 8 nm, for example about 5 nm or about 6 nm may be selectively deposited on the first surface of the substrate.

### General Process

In the methods according to the current disclosure, a substrate is provided in a reaction chamber, a silicon precursor comprising silicon and halogen is provided into the reaction chamber in a vapor phase, and a nitrogen precursor is provided into the reaction chamber in vapor phase to form material comprising silicon and nitrogen on the first surface of the substrate. The silicon precursor and the nitrogen precursor form material comprising silicon and nitrogen on the first surface. In some embodiments, the silicon precursors according to the current disclosure does not contain oxygen. Thus, in some embodiments, the silicon precursor is oxygen-free. In some embodiments, the silicon precursors according to the current disclosure does not contain nitrogen. Thus, in some embodiments, the silicon precursor is nitrogen-free.

The terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. However, a reactant may also contribute to the resulting compound or element in certain embodiments.

In some embodiments, a precursor is provided in a mixture of two or more compounds. In a mixture, the other compounds in addition to the precursor may be inert compounds or elements. In some embodiments, a precursor is substantially or completely formed of a single compound. In some embodiments, a precursor is provided in a composition. Composition may be a solution or a gas in standard conditions.

The current disclosure relates to a selective deposition process. Selectivity can be given as a percentage calculated by [(deposition on first surface)−(deposition on second surface)]/(deposition on the first surface). Deposition can be measured in any of a variety of ways. In some embodiments, deposition may be given as the measured thickness of the deposited material. In some embodiments, deposition may be given as the measured amount of material deposited.

In some embodiments, selectivity of deposition of the material comprising silicon and nitrogen on the first surface relative to the second surface is greater than about 50%. In some embodiments, selectivity is greater than about 75% or greater than about 85%. In some embodiments, selectivity is greater than about 90% or greater than about 93%. In some embodiments, selectivity is greater than about 95% or greater than about 98%. In some embodiments, selectivity is greater than about 99% or even greater than about 99.5%. In embodiments, the selectivity can change over the duration or thickness of a deposition.

In some embodiments, deposition only occurs on the first surface and does not occur on the second surface. In some embodiments, deposition on the first surface of the substrate relative to the second surface of the substrate is at least about 80% selective, which may be selective enough for some particular applications. In some embodiments the deposition on the first surface of the substrate relative to the second surface of the substrate is at least about 50% selective, which may be selective enough for some particular applications. In some embodiments the deposition on the first surface of the substrate relative to the second surface of the substrate is at least about 10% selective, which may be selective enough for some particular applications.

In some embodiments, the method does not comprise providing a metal-containing reactant into the reaction chamber. In some embodiments, the method does not comprise providing an aluminum-containing reactant into the deposition chamber. Not providing metal-containing reactants during the process may have the advantage of avoiding halogen and metal-induced defects in the material. However, in some embodiments, the method comprises providing a metal-containing reactant into the reaction chamber, and in some embodiments, the method comprises providing an aluminum-containing reactant into the deposition chamber.

In one aspect, a method of depositing material comprising silicon and nitrogen on a first surface of a substrate relative to a second surface of the same substrate is envisaged, in which the method comprises passivating the second surface; contacting the substrate with a vapor-phase silicon precursor comprising silicon and halogen; and contacting the substrate with a vapor-phase nitrogen precursor to form material comprising silicon and nitrogen on the first surface.

### Cyclic Deposition Process

In some embodiments, cyclic vapor deposition, for example, cyclic CVD or atomic layer deposition (ALD) process, is used to deposit material comprising silicon and nitrogen. After selective deposition of the material comprising silicon and nitrogen is completed, further processing can be carried out to form the desired structures.

In the current disclosure, the deposition process may comprise a cyclic deposition process, such as an atomic layer deposition (ALD) process or a cyclic chemical vapor deposition (CVD) process. The term “cyclic deposition process” can refer to the sequential introduction of precursor(s) and/or reactant(s) into a reaction chamber to deposit material, such as material comprising silicon and nitrogen, on a substrate. Cyclic deposition includes processing techniques such as atomic layer deposition (ALD), cyclic chemical vapor deposition (cyclic CVD), and hybrid cyclic deposition processes that include an ALD component and a cyclic CVD component. The process may comprise a purge step between providing precursors or between providing a precursor and a reactant in the reaction chamber.

The process may comprise one or more cyclic phases. For example, pulsing of silicon precursor and nitrogen precursor may be repeated. In some embodiments, the process comprises or one or more acyclic phases. In some embodiments, the deposition process comprises the continuous flow of at least one precursor. In such an embodiment, the process comprises a continuous flow of a silicon precursor or a nitrogen precursor. In some embodiments, one or more of the precursors and/or reactants are provided in the reaction chamber continuously.

The term “atomic layer deposition” (ALD) can refer to a vapor deposition process in which deposition cycles, such as a plurality of consecutive deposition cycles, are conducted in a reaction chamber. The term atomic layer deposition, as used herein, is also meant to include processes designated by related terms, such as chemical vapor atomic layer deposition, when performed with alternating pulses of precursor(s)/reactant(s), and optional purge gas(es). Generally, for ALD processes, during each cycle, a precursor is introduced to a reaction chamber and is chemisorbed to a deposition surface (e.g., a substrate surface that may include a previously deposited material from a previous ALD cycle or other material), forming about a monolayer or sub-monolayer of material that does not readily react with additional precursor (i.e., a self-limiting reaction). Thereafter, in some cases, another precursor or a reactant may subsequently be introduced into the process chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a silicon precursor into the reaction chamber. In some embodiments, the cyclic deposition process comprises purging the reaction chamber after providing a nitrogen precursor into the reaction chamber. In some embodiments, the cyclic deposition process comprises purging the reaction chamber after providing a silicon precursor into the reaction chamber, and after providing a nitrogen precursor into the reaction chamber.

CVD-type processes may be characterized by vapor deposition which is not self-limiting. They typically involve gas phase reactions between two or more precursors and/or reactants. The precursor(s) and reactant(s) can be provided simultaneously to the reaction space or substrate, or in partially or completely separated pulses. However, CVD may be performed with a single precursor, or two or more precursors that do not react with each other. The single precursor may decompose into reactive components that are deposited on the substrate surface. The decomposition may be brought about by plasma or thermal means, for example. The substrate and/or reaction space can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap.

The reaction chamber can form part of an atomic layer deposition (ALD) assembly. The reaction chamber can form part of a chemical vapor deposition (CVD) assembly. The assembly may comprise a single-wafer reactor. The assembly may comprise a dual-wafer reactor. The assembly may comprise a quadruple-wafer reactor. Alternatively, the reactor may be a batch reactor. The assembly may comprise one or more multi-station deposition chambers. Various phases of method can be performed within a single reaction chamber or they can be performed in multiple reaction chambers, such as reaction chambers of a cluster tool. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors. The material comprising silicon and nitrogen according to the current disclosure may be deposited in a cross-flow reaction chamber. The material comprising silicon and nitrogen according to the current disclosure may be deposited in a showerhead-type reaction chamber.

In some embodiments, the passivation, the silicon precursor and the nitrogen precursor are all provided into the reaction chamber during one deposition cycle. In such embodiments, a deposition process comprises at least one deposition cycle in which the passivation, the silicon precursor and the nitrogen precursor are provided into the reaction chamber. In some embodiments, substantially all the deposition cycles of a deposition process comprise providing the passivation, the silicon precursor and the nitrogen precursor into the reaction chamber. Such deposition schemes may be denoted “ABC” deposition schemes, wherein A denotes providing a passivation, such as silylation or depositing an organic polymer, into the reaction chamber, B denotes providing a silicon precursor into the reaction chamber and C denotes providing a nitrogen precursor into the reaction chamber. The reaction chamber may be purged after providing the passivation (or between two components of depositing a passivation through MLD), the silicon precursor and/or the nitrogen precursor into the reaction chamber. The ABC deposition cycle may be repeated a predetermined number of times to achieve desired thickness of material comprising silicon and nitrogen [n(A+B+C)], wherein n is the number of deposition cycles. For example, n may be from 1 to about 1,000, or from about 5 to about 1,000, or from about 10 to about 1,000, or from about 100 to about 1,000. In some embodiments, n is from about 3 to about 500, or from about 5 to about 500, or from about 10 to about 500, or from about 50 to about 500. In some embodiments, n is from about 50 to about 300, or from about 10 to about 200, or from about 200 to about 600. The number of repetitions of the deposition cycle depends on the per-cycle growth rate (gpc) of the material comprising silicon and nitrogen and of the desired thickness of the material. The passivation may be provided to the reaction chamber holding the substrate in a single pulse or in a sequence of multiple pulses, such as in MLD. There may be a purge between two consecutive passivation component pulses. The silicon precursor may be provided to the reaction chamber holding the substrate in a single pulse or in a sequence of multiple pulses. In some embodiments, the silicon precursor is provided in a single long pulse. In some embodiments, the silicon precursor is provided in multiple shorter pulses, such as from 2 to about 30 pulses. For example, a master cycle may comprise providing a passivation agent into the rection chamber in a single pulse, then providing the silicon precursor into the reaction chamber in multiple pulses, for example, in about 15 to about 25 pulses, and then providing a nitrogen precursor into the reaction chamber in a single pulse. The pulses may be provided sequentially. There may be a purge between two consecutive silicon precursor pulses.

In some embodiments, a deposition process according to the current disclosure comprises at least one deposition cycle that does not contain providing the passivation into the reaction chamber. Therefore, in one aspect, a method of selectively depositing material comprising silicon and nitrogen on a first surface of a substrate relative to a second surface of the substrate by a cyclic deposition process is disclosed, in which the method comprises providing a substrate in a reaction chamber, providing a passivation to the reaction chamber in a vapor phase and performing a material comprising silicon and nitrogen subcycle. The material comprising silicon and nitrogen subcycle comprises alternately and sequentially providing a silicon precursor comprising silicon and halogen into the reaction chamber in a vapor phase and providing a nitrogen precursor comprising nitrogen and hydrogen into the reaction chamber in vapor phase, to form material comprising silicon and nitrogen on the first surface.

In such embodiments, the process comprises a master cycle having a passivation and a deposition subcycle. Passivating may in itself form a subcycle, when forming the passivation comprises providing more than one chemical into the reaction chamber. The passivation may comprise providing a passivation agent into the reaction chamber and purging the reaction chamber. The passivation may comprise providing a passivation agent into the reaction chamber and not purging the reaction chamber. The deposition subcycle may comprise providing a silicon precursor into the reaction chamber, optionally purging the reaction chamber, providing a nitrogen precursor into the reaction chamber, and, again optionally, purging the reaction chamber. Such a deposition scheme may be described as n[A+m(B+C)], wherein A denotes passivation, B denotes providing a silicon precursor into the reaction chamber and C denotes providing a nitrogen precursor into the reaction chamber. If the reaction chamber is purged after providing a passivation or a precursor into the reaction chamber, the phase A, B and/or C, respectively, comprises the purge. The number of master cycles (n) may vary according to growth speed (GPC) and desired material thickness as indicated above. m may be varied from process to process to optimize selectivity and efficiency of the deposition process.

### Purging

As used herein, the term “purge” may refer to a procedure in which vapor phase precursors and/or vapor phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of gases which react with each other. However, purging may be effected between two pulses of gases that do not react with each other. For example, a purge, or purging may be provided between pulses of two precursors or between a passivation and a precursor. Purging may avoid, or at least reduce, gas-phase interactions between the two gases reacting with each other. It shall be understood that a purge can be effected either in time or in space, or both. For example in the case of temporal purges, a purge step can be used e.g. in the temporal sequence of providing a first precursor to a reactor chamber, providing a purge gas to the reactor chamber, and providing a second precursor to the reactor chamber, wherein the substrate on which a material is deposited does not move. For example in the case of spatial purges, a purge step can take the following form: moving a substrate from a first location to which a first precursor is supplied to a second location to which a second precursor is supplied. Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s. However, other purge times can be utilized if necessary, such as where highly conformal step coverage over extremely high aspect ratio structures or other structures with complex surface morphology is needed, or in specific reactor types, such as a batch reactor, may be used.

### Thermal Process

In some embodiments, the cyclic deposition process according to the current disclosure comprises a thermal deposition process. In thermal deposition, the chemical reactions are promoted by increased temperature relevant to ambient temperature. Generally, temperature increase provides the energy needed for the formation of material comprising silicon and nitrogen in the absence of other external energy sources, such as plasma, radicals, or other forms of radiation. In some embodiments, the vapor deposition process according to the current disclosure is a thermal ALD process. A thermal process may be preferred in selective vapor deposition processes over plasma-enhanced processes since plasma exposure may damage the passivation or alter its inhibition properties. However, one or more plasmas may be utilized in other process phases, such as etching away unwanted materials.

In some embodiments, material comprising silicon and nitrogen may be deposited at a temperature from about 150° C. to about 500° C., such as at a temperature between about 200° C. and about 450° C. For example, material comprising silicon and nitrogen may be deposited at a temperature from about 200° C. to about 400° C., or at a temperature from about 250° C. to about 350° C., or at a temperature from about 300° C. to about 375° C. The passivation may be provided into the reaction chamber at the same temperature as the material comprising silicon and nitrogen is deposited. Alternatively, the temperature during providing the passivation into the reaction chamber is different from the temperature at which the material comprising silicon and nitrogen is deposited. In some embodiments, the substrate is heated before providing the passivation into the reaction chamber. In embodiments comprising depositing a passivation blocking layer and a passivation layer, the temperature for the deposition of said layers may be independently selected. For example, a temperature during a silylation process may be from about 50° C. to about 500° C., or from about 100° C. to about 300° C. As another example, a polyimide-comprising passivation layer may be deposited at temperatures below 190° C., and subsequently heat-treated at a temperature of about 190° C. or higher (such as 200° C. or 210° C.) to increase the proportion of the organic material from polyamic acid to polyimide, and to improve the passivation properties of the passivation layer.

### Pressure

The methods according to the current disclosure may be performed in reduced pressure. In some embodiments, a pressure within the reaction chamber during the deposition process according to the current disclosure is less than about 50 Torr, or a pressure within the reaction chamber during the deposition process is between about 0.1 Torr and about 50 Torr, or between about 0.1 Torr and about 20 Torr, or between about 0.1 Torr and about 10 Torr. In some embodiments, a pressure within the reaction chamber during the deposition process is less than about 10 Torr, or less than about 6 Torr, or less than about 3 Torr, or about 2 Torr or less.

A pressure in a reaction chamber may be selected independently for different process steps. In some embodiments, at least two different pressures are used during a deposition cycle.

In some embodiments, a first pressure is used during providing the passivation into the reaction chamber, and a second pressure is used when providing the silicon precursor into the reaction chamber.

### Silicon Precursor

As used herein, “silicon precursor” includes a gas or a material that can become gaseous and that can be represented by a chemical formula that includes silicon and a halogen. In some embodiments, the silicon precursor comprises a halosilane. In some embodiments, the halosilane is selected from a group consisting of monosilanes, disilanes and trisilanes. In some embodiments, the silicon precursor is oxygen-free. In some embodiments, the silicon precursor is nitrogen-free. In some embodiments, the silicon precursor does not comprise an alkylamide. In some embodiments, the silicon precursor does not comprise an alkylaminosilane. In some embodiments, the silicon precursor does not comprise an iodosilane. In some embodiments, the silicon precursor does not comprise a diiodosilane. In some embodiments, the silicon precursor comprises nitrogen. In some embodiments, the silicon precursor comprises a Si—N bond. In some embodiments, the silicon precursor comprises a silazane. In some embodiments, the silazane is a disilazane. In some embodiments, the silicon precursor comprises a secondary amine. In some embodiments, the silicon precursor comprises a halosilylalkane. In some embodiments, the halosilylalkane is bis(trichlorosilyl)methane.

In some embodiments, the halogen in the halosilane is selected from bromine, iodine and chlorine. In some embodiments, the halogen in the halosilane is selected from iodine and chlorine. In some embodiments, the halogen in the halosilane is selected from bromine and chlorine. In some embodiments, the halogen in the halosilane is selected from iodine and bromine. In some embodiments, the halosilane is a chlorosilane. In some embodiments, the halosilane is a bromosilane. In some embodiments, the halosilane is an iodosilane. In some embodiments, the silicon precursor is a chlorosilane. In some embodiments, the silicon precursor is a bromosilane. In some embodiments, the silicon precursor is an iodosilane. In some embodiments, the halosilane is fully halogenated. In some embodiments, the halosilane is a fully halogenated chlorosilane. In some embodiments, the silicon precursor is a fully halogenated bromosilane. In some embodiments, the silicon precursor is a fully halogenated iodosilane.

At least some of the suitable precursors may have the general formula (I):

H_{2n+2-y-z}SiₙX_{y}A_{z}, (I)

wherein, n=1-10, y=1 or more (and up to 2n+2−z), z=0 or more (and up to 2n+2−y), X is Cl, I or Br, and A is a halogen other than X. In some embodiments, n=1-5. In some embodiments, n=1-3. In some embodiments, n=1-2.

According to some embodiments, silicon precursors may comprise one or more cyclic compounds. Such precursors may have the general formula (II):

H_{2n-y-z}SiₙX_{y}A_{z}, (II)

wherein the compound of formula (II) is a cyclic compound, n 3-10, y=1 or more (and up to 2n−z), z=0 or more (and up to 2n−y), X is Cl, I or Br, and A is a halogen other than X. In some embodiments, n=3-6.

According to some embodiments, a silicon precursor comprises one or more iodosilanes. Such precursors may have the general formula (III):

H_{2n+2-y}SiₙI_{y}, (III)

wherein, n=1-5, y=1 or more (up to 2n+2−y). In some embodiments, n=1-3, and in some embodiments, n=1-2.

According to some embodiments, a silicon precursor comprises one or more bromosilanes. Such precursors may have the general formula (IV):

H_{2n+2-y}SiₙBr_{y}, (IV)

wherein, n=1-5, y=1 or more (up to 2n+2−y). In some embodiments, n=1-3, and in some embodiments, n=1-2.

According to some embodiments, a silicon precursor comprises one or more chlorosilanes. Such precursors may have the general formula (V):

H_{2n+2-y}SiₙCl_{y}, (V)

wherein, n=1-5, y=1 or more (up to 2n+2−y). In some embodiments, n=1-3, and in some embodiments, n=1-2.

According to some embodiments, a suitable silicon precursor can include at least compounds having any one of the general formulas (I) through (V). In general formulas (I) through (V), halides/halogens can include Cl, Br and I. In some embodiments, a silicon precursor comprises a halosilane selected from a group consisting of SiI₄, SiI₃H, SiI₂H₂, SiIH₃, Si₂I₆, Si₂I₅H, Si₂I₄H₂, Si₂I₃H₃, Si₂I₂H₄, Si₂IH₅, Si₃I₈, Si₃I₇H, Si₃I₆H₂, Si₃I₅H₃, Si₃I₄H₄, Si₃I₃H₅, Si₃I₂H₆ or Si₃IH₇.

In some embodiments, a silicon precursor comprises a halosilane selected from a group consisting of SiBr₄, SiBr₃H, SiBr₂H₂, SiBrH₃, Si₂Br₆, Si₂Br₅H, Si₂Br₄H₂, Si₂Br₃H₃, Si₂Br₂H₄, Si₂BrH₅, Si₃Br₈, Si₃Br₇H, Si₃Br₆H₂, Si₃Br₅H₃, Si₃Br₄H₄, Si₃Br₃H₅, Si₃Br₂H₆ or Si₃BrH₇.

In some embodiments, a silicon precursor comprises a halosilane selected from a group consisting of SiCl₄, SiCl₃H, SiCl₂H₂, SiClH₃, Si₂Cl₆, Si₂Cl₅H, Si₂Cl₄H₂, Si₂Cl₃H₃, Si₂Cl₂H₄, Si₂ClH₅, Si₃Cl₈, Si₃Cl₇H, Si₃Cl₆H₂, Si₃Cl₅H₃, Si₃Cl₄H₄, Si₃Cl₃H₅, Si₃Cl₂H₆ or Si₃ClH₇.

In some embodiments, a silicon precursor comprises two or more halosilanes. Depending on the selected silicon precursor, it may be liquid or gaseous in the precursor vessel upon vaporization. Also solid precursors may be used.

### Nitrogen Precursor

As used herein, “nitrogen precursor” includes a gas or a material that can become gaseous and that can be represented by a chemical formula that includes nitrogen. In some embodiments, the nitrogen precursor comprises nitrogen and hydrogen. In some embodiments, the nitrogen precursor consists essentially of, or consists of, nitrogen and hydrogen. In some cases, the nitrogen precursor does not include molecular nitrogen.

In some embodiments, the nitrogen precursor is selected from a group consisting of molecular nitrogen (N₂), ammonia (NH₃), hydrazine (NH₂NH₂) and a hydrazine derivative, such as tert-butylhydrazine. In some embodiments, the nitrogen precursor does not contain carbon, i.e. it is carbon-free. In some embodiments, the nitrogen precursor does not contain silicon, i.e. it is silicon-free. Depending on the selected nitrogen precursor, it may be liquid or gaseous in the precursor vessel upon vaporization. Also solid precursors may be used.

In some embodiments, the nitrogen precursor comprises ammonia. In some embodiments, the nitrogen precursor consists essentially of, or consists of ammonia. In some embodiments the nitrogen precursor comprises an alkylamine. In some embodiments the nitrogen precursor consists essentially of or consists of an alkylamine. Examples of alkylamines include dimethylamine, n-butylamine and tert-butylamine.

In some embodiments, the nitrogen precursor comprises hydrazine. In some embodiments, the nitrogen precursor consists essentially of, or consists of hydrazine. In some embodiments the nitrogen precursor comprises hydrazine substituted by one or more alkyl or aryl substituents. In some embodiments the nitrogen precursor consists essentially of, or consists of hydrazine substituted by one or more alkyl or aryl substituents. In some embodiments, the hydrazine derivative comprises an alkyl-hydrazine including at least one of: tert-butylhydrazine (C₄H₉N₂H₃), methylhydrazine (CH₃NHNH₂), 1,1-dimethylhydrazine ((CH₃)₂NNH₂), 1,2-dimethylhydrazine (CH₃)NHNH(CH₃), ethylhydrazine, 1,1-diethylhydrazine, 1-ethyl-1-methylhydrazine, isopropylhydrazine, phenylhydrazine, 1,1-diphenylhydrazine, 1,2-diphenylhydrazine, N-aminopiperidine, N-aminopyrrole, N-aminopyrrolidine, N-methyl-N-phenylhydrazine, 1-amino-1,2,3,4-tetrahydroquinoline, N-aminopiperazine, 1,1-dibenzylhydrazine, 1,2-dibenzylhydrazine, 1-ethyl-1-phenylhydrazine, 1-aminoazepane, 1-methyl-1-(m-tolyphydrazine, 1-ethyl-1-(p-tolyl)hydrazine, 1-aminoimidazole, 1-amino-2,6-dimethylpiperidine, N-aminoaziridine, or azo-tert-butane.

In some embodiments, the nitrogen precursor may comprise ammonium hydroxide (NH₄OH). Without limiting the current disclosure to any specific theory, the use of ammonium hydroxide may lead into the incorporation of oxygen into the deposited material comprising silicon and nitrogen. This may have advantages in some applications of the method.

### DRAWINGS

The disclosure is further explained by the following exemplary embodiments depicted in the drawings. The illustrations presented herein are not meant to be actual views of any particular material, structure, device or an apparatus, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

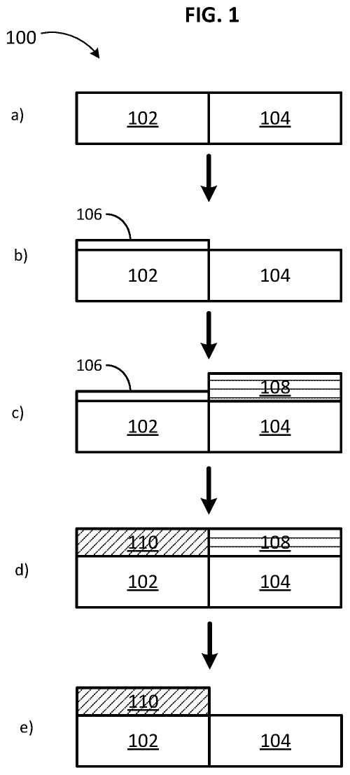

FIG. 1, panels a) to e) illustrates an embodiment of a method according to the current disclosure schematically. In the drawing, a substrate 100 comprising a first surface 102 and a second surface 104 is depicted. The first surface 102 is blocked relative to the second surface 104 by a blocking layer 106, the second surface 104 is selectively passivated by an organic passivation layer 108 relative to the first surface 102 comprising the blocking layer 106, followed by selective deposition of material comprising silicon and nitrogen 110 on the first surface 102 relative to the passivated second surface 104.

Panel a) illustrates a substrate 100 having two surfaces 102, 104 having different material properties. For example, the first surface 102 may be a dielectric surface. The first surface 102 may comprise, consist essentially of, or consist of silicon oxide-based material or another dielectric material, such as silicon-based material described in this disclosure. The second surface 104 may comprise, consist essentially of, or consist of a metal, such as Cu, W or Mo, or a metallic material, such as TiN.

Panel b) shows the substrate 100 of panel a) after selective blocking of the first surface 102, such as by silylation. For example, a blocking 106 may be formed selectively on a dielectric surface by exposing the substrate 100 to a silylating agent, such as alyltrimethylsilane (TMS-A), chlorotrimethylsilane (TMS-Cl), N-(trimenthylsilyl)imidazole (TMS-Im), octadecyltrichlorosilane (ODTCS), hexamethyldisilazane (HMDS), or N-(trimethylsilyl)dimethylamine (TMSDMA). Although depicted in FIG. 1 as a layer, the blocking of the first surface may be very thin.

Panel c) shows the substrate 100 of panel b) after selective deposition of an organic passivation layer 108 on the second surface 104, such as by formation of a polyimide-comprising layer.

Panel d) shows the substrate 100 of panel c) following selective deposition of material comprising silicon and nitrogen 110 on the first surface 102 relative to the passivated second surface 104. The material comprising silicon and nitrogen 110 is deposited by providing a silicon precursors comprising a halosilane, such as octachlorotrisilane, hexachlorodisilane, tetrachlorosilane or a tetraiodosilane into the reaction chamber and providing a nitrogen precursor, such as ammonia, into the reaction chamber in accordance with the current disclosure. The silicon precursor and the nitrogen precursor may react on the first surface of the substrate, leading to the deposition of material comprising silicon and nitrogen, such as silicon nitride-, silicon oxynitride- or silicon carbonitride -comprising material, on the first surface.

In tests performed by the inventors, ammonia was used as a nitrogen precursor, leading to the selective deposition of material comprising silicon and nitrogen on a native silicon oxide surface relative to a surface comprising tungsten. Under the tested conditions, some oxygen was incorporated into the deposited material. This, however, is likely to be an artifact of the exposure of the deposited material to ambient atmosphere after the deposition process. The tests were performed at a temperatures of below 400° C., for example at a temperature of 300° C. The chlorine content of the deposited material comprising silicon and nitrogen was below 2 at-%. The passivation on the second (metal) surface was polyimide-comprising material, and the first (dielectric) surface of the substrate was blocked by N-(trimethylsilyl)dimethylamine prior to passivating the second surface.

Any material comprising silicon and nitrogen 110 deposited on the second surface 104, such as on the polymer passivated metal layer 108, can be removed by a treatment, such as an etch-back process. Because the material comprising silicon and nitrogen is deposited selectively on the first surface 102, any material comprising silicon and nitrogen 110 left on the passivation layer 108 will be thinner than the material comprising silicon and nitrogen deposited on the first surface 102. Accordingly, the treatment can be controlled to remove all, or substantially all, of the material comprising silicon and nitrogen from over the second surface 104 without removing all of the material comprising silicon and nitrogen 110 from over the first surface. Repeated selective deposition and etching back in this manner can result in an increasing thickness of the material comprising silicon and nitrogen 110 on the first surface 102 with each cycle of deposition and etch. Repeated selective deposition and etching back in this manner can also result in increased overall selectivity of the material comprising silicon and nitrogen 110 deposition on the first surface 102, as each cycle of deposition and etch leaves a clean passivation layer 108 over which the selective material comprising silicon and nitrogen 110 is deposited at a lower rate compared to the first surface 102. In other embodiments, material comprising silicon and nitrogen over the second surface 104 may be removed during subsequent removal of the passivation layer 108. In some embodiments, the method comprises at least one etch-back step. In some embodiments, etching is used as a post-deposition process to clean up the final surfaces, and/or to remove passivation.

Panel e) shows the substrate of panel d) after a post-deposition treatment to remove the passivation layer 108 from the second surface 104, such as by an etch process. In some embodiments, the etch process may comprise exposing the substrate 100 to a plasma. In some embodiments, the plasma may comprise oxygen atoms, oxygen radicals, oxygen plasma, or combinations thereof. In some embodiments, the plasma may comprise hydrogen atoms, hydrogen radicals, hydrogen plasma, or combinations thereof. In some embodiments, the plasma may comprise noble gas species, for example Ar or He species. In some embodiments, the plasma may consist essentially of noble gas species. In some embodiments, the plasma may comprise other species, for example nitrogen atoms, nitrogen radicals, nitrogen plasma, or combinations thereof. In some embodiments, the etch process may comprise exposing the substrate to an etchant comprising oxygen, for example O₃. In some embodiments, the substrate may be exposed to an etchant at a temperature of between about 30° C. and about 500° C., or between about 100° C. and about 400° C., or between about 100° C. and about 300° C. In some embodiments, the etchant may be supplied in one continuous pulse or may be supplied in multiple pulses. The removal of the passivation layer 108 can be used to lift-off any remaining material comprising silicon and nitrogen from over the second surface, either in a complete removal of the passivation layer 108 or in a partial removal of the passivation layer 108 in a cyclical selective deposition and removal.

Although not depicted in FIG. 1, the deposition scheme could be reversed by omitting the deposition of the blocking on the first surface. Through appropriate selections of the processing conditions, the passivation 108 could be formed on the dielectric surface 102—which would be an example of a second surface in such an embodiment. Consequently, the material comprising silicon and nitrogen would be deposited on the metal surface 104—which would be a first surface in such an embodiment. The passivation on the dielectric surface may be polyimide-comprising material, or material that is used to block the first surface in the first example of FIG. 1. In cases in which alkylamines, for example N-(trimethylsilyl)dimethylamine, are used in passivation of the dielectric surface, the passivation may be repeated during the deposition to avoid loss of selectivity during the process. In an exemplary test. 4.5 nm of material comprising silicon and nitrogen was deposited on tungsten-containing surface relative to 0.6 nm on a native silicon dioxide surface. Both polyimide- and N-(trimethylsilyl)dimethylamine were tested as passivation at 300° C. Neither of them inhibited the growth of material comprising silicon and nitrogen on metal surface. The growth of material comprising silicon and nitrogen after 200 deposition cycles on passivated silicon oxide surface was less than 1 nm, and even less than 0.5 nm, whereas on metal, about 7 nm of material was deposited. The selectivity may be further improved by performing an etch-back during the deposition and/or by renewing the passivation during the deposition.

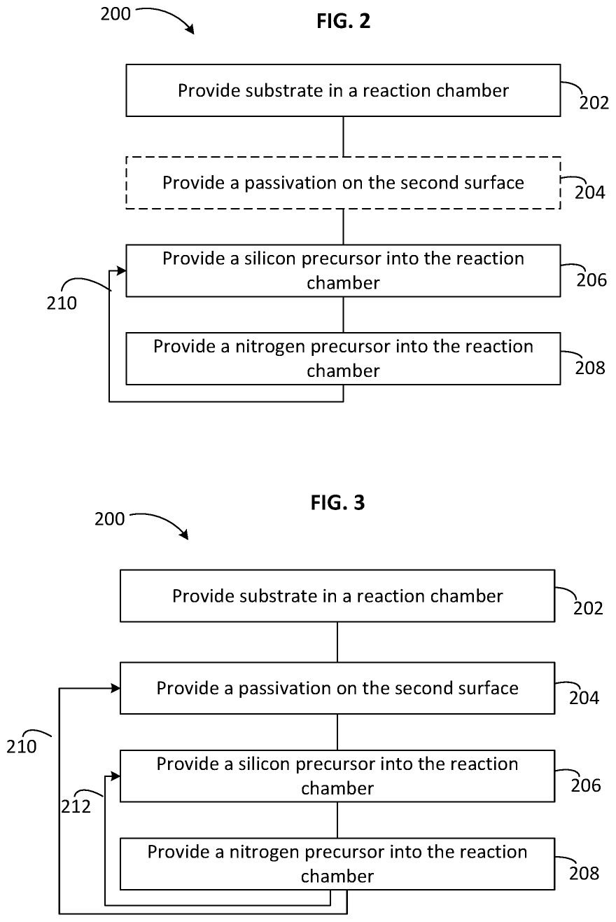

FIG. 2 is a block diagram of exemplary embodiments of a method according to the current disclosure. First, a substrate is provided in a reaction chamber at stage 202. The substrate comprises a first surface and a second surface as described in the current disclosure. For example, the first surface may be a dielectric surface, and the second surface may be a metal surface. In some embodiments, the first surface is a metal or metallic surface, and the second surface is a dielectric surface, such as silicon-containing dielectric surface. The substrate may be heated at stage 202 prior to providing a silicon precursor (or optional passivation).

At stage 204, the second surface is optionally passivated. In some embodiments, the second surface comprises a previously applied passivation, so that stage 204 is not needed. In an exemplary embodiment, the passivation may comprise, for example, polyimide or silicon-containing alkylamine. The passivation may allow the selective deposition of the material comprising silicon and nitrogen on the first surface. The reaction chamber may be purged after performing the passivation 204. Purging is not indicated in FIG. 2, but it may be optionally included in stage 204, and/or in any of the other stages of the process.

At stage 206, a silicon precursor comprising a halosilane is provided into the reaction chamber in a vapor phase. In an exemplary embodiment, the silicon precursor is octachlorotrisilane or tetraiodosilane. The silicon precursor is selectively chemisorbed on the first surface relative to the second surface of the substrate. The silicon precursor may be provided into the reaction chamber (i.e. pulsed) for about 0.2 to 10 seconds, for example, about 0.5 seconds, about 1 second, about 3 seconds, about 5 seconds or about 6 seconds. In some embodiments, the silicon precursor is provided into the reaction chamber in multiple, such as 2, 5 or 7, consecutive pulses. In some embodiments, the silicon precursor is provided into the reaction chamber in a single pulse for each deposition cycle. The reaction chamber may be purged after a silicon precursor pulse. Purging is not indicated in FIG. 2, but it may be optionally included in stage 206.

At stage 208, a nitrogen precursor is provided into the reaction chamber in a vapor phase. In an exemplary embodiment, the nitrogen precursor is ammonia. The nitrogen precursor reacts with the chemisorbed silicon precursor to form material comprising silicon and nitrogen, such as silicon nitride, or silicon oxynitride, on the first surface of the substrate. The reaction chamber may be purged after a nitrogen precursor pulse. Purging is not indicated in FIG. 2, but it may be optionally included in stage 208.

The deposition process according to the current disclosure is a cyclic deposition process. Thus, at loop 210, the deposition cycle is initiated again. The deposition cycle may be repeated as many times as needed to deposit a desired amount of material comprising silicon and nitrogen on the substrate. For example, the deposition cycle may be performed from 2 to about 1,000 times, or from about 10 to about 500 times, or from about 10 to about 500 times, or from about 50 to 300 times. For example, the deposition cycle may be performed about 70 times, about 100 times, about 150 times, about 200 times, about 400 times or about 600 times. As indicated above, the deposition is performed at a temperature from about 150° C. to about 500° C., such as at about 250° C. or at about 300° C.

Although not detailed in the current disclosure, the process may comprise additional steps, for example refreshing any blocking or passivation that may be necessary for the continued selective deposition, thermal treatments, intermediate etch-back or post-deposition etching. In some embodiments, the selective deposition of material comprising silicon and nitrogen on the first surface does not damage a passivation, such as an organic passivation layer, present on the second surface. Further, in some embodiments, the material comprising silicon and nitrogen is substantially not deposited on the passivation.

In some embodiments, the material comprising silicon and nitrogen deposited according to the current disclosure comprises predominantly, such as at least 55 at. % or at least 70 at. %, silicon and nitrogen. Although not depicted in the drawings 2 to 4, it is possible for the phases of the deposition process to overlap. For example, phases 206 and 208 may be performed at least partially simultaneously. In some embodiments, phases 206 and 208 are performed at least partially simultaneously.

FIG. 3 is a block diagram of additional exemplary embodiments of a method according to the current disclosure. Stages 202, 204, 206 and 208 are performed similarly to the embodiments described in FIG. 2. In the embodiments of FIG. 3, providing a passivation on the second surface is a part of a master cycle, which also includes stages 206 and 208. Stages 206 and 208 form a deposition subcycle that is performed at least 2 times (loop 212) before a master cycle, comprising also stage 204, and indicated by loop 210, is repeated. The number of repetitions of the deposition subcycle 212 may vary according to the specific process. For example, the deposition subcycle 212 could be performed at least twice, or at least 10 times, in each master cycle, before the passivation is renewed through loop 210. In some embodiments, the deposition subcycle is performed from 2 to about 50 times, for example about 10 or about 20 or about 30 times, in each master cycle. A master cycle may be performed from 1 to about 500 times, depending on the target thickness of the deposited material.

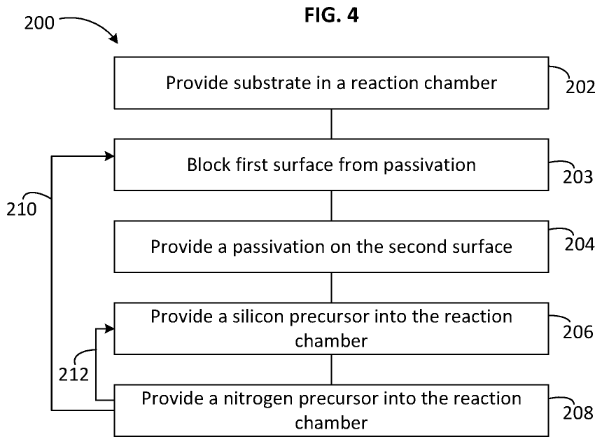

FIG. 4 is a block diagram of yet additional exemplary embodiments of a method according to the current disclosure. Stages 202, 204, 206 and 208 are performed similarly to the embodiments described in FIGS. 2 and 3. In the embodiments of FIG. 4, stages 206 and 208 form a deposition subcycle (loop 212) as in the embodiment of FIG. 3. However, in the embodiments of FIG. 4, stage 204 of providing a passivation on the second surface is performed after stage 203 of blocking the first surface from passivation. The parameters of stage 203 may be independently selected relative to the parameters of stage 204 for optimizing the blocking and passivation, respectively. Thus, master cycle 210 in the embodiments of FIG. 4 comprises blocking 203, passivation 204 and at least two deposition subcycles 212. Although not depicted in FIG. 4, a master cycle 210 may omit blocking, and contain only passivation 204 and the deposition subcycle 212 as in FIG. 3. The number of repetitions of the blocking 203, passivation 204 and the deposition subcycle 212 may vary, and the ratio between these parts of the process may also vary.

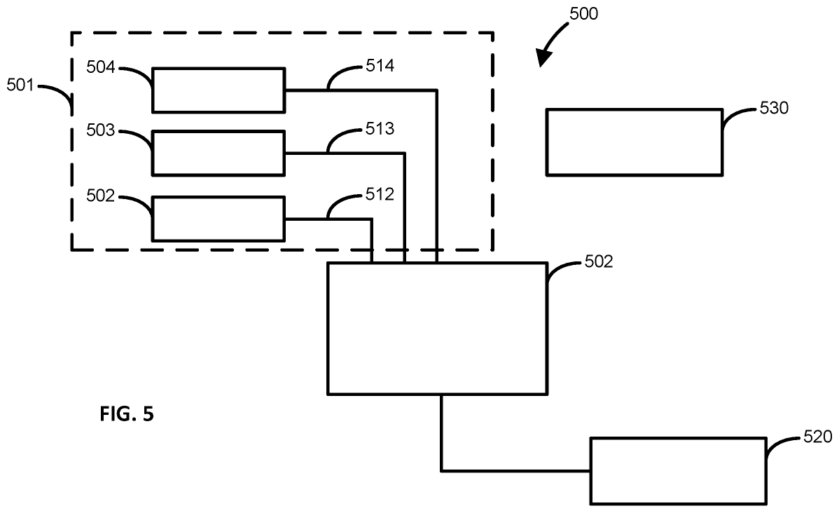

FIG. 5 illustrates a deposition assembly 500 according to the current disclosure in a schematic manner. In one aspect, a deposition assembly for selectively depositing material comprising silicon and nitrogen on a first surface of a substrate relative to a second surface of the same substrate is disclosed. The deposition assembly comprises one or more reaction chambers constructed and arranged to hold the substrate, a precursor injector system constructed and arranged to provide a silicon precursor and a nitrogen precursor into the reaction chamber in a vapor phase. The deposition assembly comprises a first reactant vessel constructed and arranged to contain the silicon precursor and a second reactant vessel constructed and arranged to contain the nitrogen precursor. The deposition assembly is constructed and arranged to provide the silicon precursor and the nitrogen precursor via the precursor injector system to the reaction chamber to deposit material comprising silicon and nitrogen on the first surface of the substrate.

The deposition assembly 500 may comprise optional third and further reactant vessels 504 constructed and arranged to contain additional reactants, such as passivation or blocking agents. The deposition assembly 500 may comprise a passivation system for providing the passivation agent—which may comprise one, two or more reactants—into the deposition chamber. For example, for a polyimide-comprising passivation layer, two precursors may be used for molecular layer deposition of the passivation material. The third or further reactant vessels may form a part of the passivation system. Thus, in some embodiments, the deposition assembly further comprises a passivation system constructed and arranged to provide a passivation agent into a reaction chamber of the deposition assembly. The optional third and further reactant vessels 504 may alternatively contain additional reactants used for modifying the deposited material. For example, a third or a further reactant vessel 504 may be constructed and arranged to hold an etchant.

The deposition assembly 500 can be used to perform a method as described herein. In the illustrated example, deposition assembly 500 includes one or more reaction chambers 502, a precursor injector system 501, a first reactant vessel 502, a second reactant vessel 503, an optional third (and further) reactant vessel 504, an exhaust source 520, and a controller 530. The deposition assembly 500 may comprise one or more additional gas sources (not shown), such as an inert gas source, a carrier gas source and/or a purge gas source. In embodiments, in which blocking and/or passivation is performed in the same deposition assembly, the deposition assembly 500 may comprise the corresponding sources. Reaction chamber 502 can include any suitable reaction chamber, such as an ALD or CVD reaction chamber as described herein.

The first reactant vessel 502 can include a vessel and a silicon precursor as described herein—alone or mixed with one or more carrier (e.g., inert) gases. A second reactant vessel 503 can include a vessel and a nitrogen precursor as described herein—alone or mixed with one or more carrier gases. A third reactant vessel 504 can include a further reactant as described herein. Thus, although illustrated with three reactant vessels 502-504, deposition assembly 500 can include any suitable number of reactant vessels. Reactant vessels 502-504 can be coupled to reaction chamber 502 via lines 512-514, which can each include flow controllers, valves, heaters, and the like. In some embodiments, each of the silicon precursor in the first reactant vessel 502, the nitrogen precursor in the second reactant vessel 503 and/or the further reactant in the third reactant vessel 504 may be independently heated or kept at ambient temperature. In some embodiments, a reactant vessel is heated so that a precursor or a reactant reaches a suitable temperature for vaporization

Exhaust source 520 can include one or more vacuum pumps.

Controller 530 includes electronic circuitry and software to selectively operate valves, manifolds, heaters, pumps and other components included in the deposition assembly 500. Such circuitry and components operate to introduce precursors, reactants and other gases from the respective sources. Controller 530 can control timing of gas pulse sequences, temperature of the substrate and/or reaction chamber 502, pressure within the reaction chamber 502, and various other operations to provide proper operation of the deposition assembly 500. Controller 530 can include control software to electrically or pneumatically control valves to control flow of precursors, reactants and other gases into and out of the reaction chamber 502. Controller 530 can include modules such as a software or hardware component, which performs certain tasks.

Other configurations of deposition assembly 500 are possible, including different numbers and kinds of precursor and reactant vessels. For example, a reaction chamber 502 may comprise more than one, such as two or four, deposition stations. Such a multi-station configuration may have advantages if, for example, blocking, passivation and/or etching are to be performed in the same reaction chamber. Further, it will be appreciated that there are many arrangements of valves, conduits, precursor sources, and reactant sources that may be used to accomplish the goal of selectively and in coordinated manner feeding gases into reaction chamber 502. Further, as a schematic representation of a deposition assembly 500, many components have been omitted for simplicity of illustration, and such components may include, for example, various valves, manifolds, purifiers, heaters, containers, vents, and/or bypasses.

During operation of deposition assembly 500, substrates, such as semiconductor wafers (not illustrated), are transferred from, e.g., a substrate handling system to reaction chamber 502. Once substrate(s) are transferred to reaction chamber 502, one or more gases from gas sources, such as precursors, reactants, carrier gases, and/or purge gases, are introduced into reaction chamber 502.

In this disclosure, “gas” can include material that is a gas at normal temperature and pressure (NTP), a vaporized solid and/or a vaporized liquid, and can be constituted by a single gas or a mixture of gases, depending on the context. Precursors according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

In some embodiments, the substrate may be pretreated or cleaned prior to or at the beginning of the selective deposition process. In some embodiments, the substrate may be subjected to a plasma cleaning process at prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, a pretreatment or cleaning process may be carried out in the same reaction chamber as a selective deposition process. However, in some embodiments, a pretreatment or cleaning process may be carried out in a separate reaction chamber.

The particular implementations shown and described below are illustrative of the invention and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method of selectively depositing material comprising silicon and nitrogen on a first surface of a substrate relative to a second surface of the same substrate by a cyclic deposition process, the method comprising:
providing a substrate in a reaction chamber;
providing a silicon precursor comprising silicon and halogen into the reaction chamber in a vapor phase; and
providing a nitrogen precursor into the reaction chamber in a vapor phase to form the material comprising silicon and nitrogen on the first surface.

2. The method of claim 1, wherein the silicon precursor comprises a halosilane.

3. The method of claim 2, wherein the halogen in the halosilane is selected from the group consisting of iodine and chlorine.

4. The method of claim 3, wherein the halosilane is a fully halogenated chlorosilane.

5. The method of claim 1, wherein the nitrogen precursor consists of nitrogen and hydrogen.

6. The method of claim 1, wherein the second surface is passivated.

7. The method of claim 6, wherein the passivation comprises an organic polymer, a self-assembled monolayer (SAM) or a small-molecular inhibitor.

8. The method of claim 1, wherein the first surface is a conductive surface.

9. The method of claim 8, wherein the first surface comprises elemental metal.

10. The method of claim 9, wherein the elemental metal is selected from the group consisting of Cu, Co, Ru, W, Ti, Al, Ta and Mo.

11. The method of claim 1, wherein the second surface comprises silicon-based dielectric material.

12. The method of claim 11, wherein the second surface comprises a low k material.

13. The method of claim 12, wherein the second surface comprises passivation.

14. The method of claim 13, wherein the passivation is selectively formed on the second surface relative to the first surface by providing a passivation agent into the reaction chamber, and wherein the passivation agent is selected from the group consisting of silylating agents and materials comprising polyimide.

15. The method of claim 1, wherein the deposited material comprising silicon and nitrogen consists essentially of, or consists of, silicon, nitrogen and hydrogen.

16. The method of claim 1, wherein the deposited material comprising silicon and nitrogen consists essentially of, or consists of silicon, nitrogen, hydrogen and a fourth element.

17. The method of claim 1, wherein the deposited material comprises silicon and nitrogen comprises less than about 4 at-%, or less than about 2 at-% halogen.

18. The method of claim 1, wherein the method does not comprise providing a metal-containing reactant into the reaction chamber.

19. A method of selectively depositing an etch stop layer, the method comprising depositing etch stop material comprising silicon and nitrogen on a first surface of a substrate relative to a second surface of the same substrate by a cyclic deposition process, the method comprising:
providing a substrate in a reaction chamber;
providing a silicon precursor comprising silicon and halogen into the reaction chamber in a vapor phase; and
providing a nitrogen precursor into the reaction chamber in a vapor phase to form the etch stop material comprising silicon and nitrogen on the first surface.

20. A deposition assembly for selectively depositing material comprising silicon and nitrogen on a first surface of a substrate relative to the second surface of the same substrate, the deposition assembly comprising:
one or more reaction chambers constructed and arranged to hold the substrate;
a precursor injector system constructed and arranged to provide a silicon precursor and a nitrogen precursor into the reaction chamber in a vapor phase;
wherein the deposition assembly comprises a first reactant vessel constructed and arranged to contain the silicon precursor; and
a second reactant vessel constructed and arranged to contain the nitrogen precursor;
and the assembly is constructed and arranged to provide the silicon precursor and the nitrogen precursor via the precursor injector system to the reaction chamber to deposit the material comprising silicon and nitrogen on the first surface.

21. The deposition assembly of claim 20, further comprising a passivation system constructed and arranged to provide a passivation agent into a reaction chamber of the deposition assembly.
